(19) United States
(12) Patent Application Publication
(10) Pub. No.: US 2018/0112326 A1
(43) Pub. Date: Apr. 26, 2018

(54) THIN SILICON SUBSTRATE FABRICATION DIRECTLY FROM SILICON MELT

(71) Applicant: Board of Regents of the Nevada System of Higher Education, on behalf of the University of Nevada,, Reno, NV (US)

(72) Inventors: Ghassan Jabbour, Phoenix, AZ (US); Hyung Woo Choi, Reno, NV (US); Dhanesh Chandra, Reno, NV (US); Mo Masoumi Danyan, Reno, NV (US)

(73) Assignee: Board of Regents of the Nevada System of Higher Education, on behalf of the University of Nevada,, Reno, NV (US)

(21) Appl. No.: 15/561,831

(22) PCT Filed: Mar. 25, 2016
(86) PCT No.: PCT/US2016/024245

§ 371 Date: Sep. 26, 2017

Related U.S. Application Data
(60) Provisional application No. 62/139,433, filed on Mar. 27, 2015.

(51) Int. Cl. C30B 11/00; C30B 29/06

(52) U.S. Cl. CPC C30B 11/008; C30B 29/06

(57) ABSTRACT

Disclosed herein are embodiments of systems and methods for making silicon substrates. The disclosed systems use a unique combination of induction heating and crucible materials to produce silicon substrates in short time periods. The disclosed methods are cost-efficient and time-efficient and can be used to obtain pure silicon substrates having a desirable thinness for commercial use.

### CROSS REFERENCE TO RELATED APPLICATION

This application claims the benefit of and priority to U.S. Provisional Application No.

62/139,433 filed on Mar. 27, 2015, which is incorporated herein by reference in its entirety.

### FIELD

The present disclosure concerns embodiments of thin silicon substrates and methods of making and using the same.

### BACKGROUND

Silicon has been an important material in electronic, optoelectronic, photonic, and renewable energy device applications. This importance is due to its excellent characteristics such as low bandgap, large charge storage capability, design flexibility, controllable dopant profile, and ecologically safe. There have been considerable efforts devoted to developing a cheap silicon wafer that will last for long periods of time; however, these methods have drawbacks that limit their usefulness in industry.

### SUMMARY

Disclosed herein are embodiments of a system for making silicon substrates, comprising an induction heater, a crucible comprising graphite, a cooling wheel, and a reaction chamber. In some embodiments, the crucible does not comprise a plurality of vertical slits. The induction heater can be positioned so as to surround at least a portion of the crucible. In some embodiments, the induction heater produces an electromagnetic current sufficient to melt a silicon substrate precursor. In some embodiments, the induction heater can be a copper coil. In some embodiments, the induction heater is used to heat the silicon substrate precursor to a temperature ranging from 1680K to 1690K in a time period ranging from 30 seconds to 10 minutes.

Also disclosed herein is a system for making silicon substrates, comprising a crucible consisting of graphite, wherein the crucible does not comprise a plurality of vertical slits, an induction heater positioned to surround at least a portion of the crucible, a copper cooling wheel positioned proximal to the crucible, and a reaction chamber that surrounds the crucible, the induction heater, and the copper cooling wheel.

Also disclosed herein are embodiments of a method for making silicon substrates, comprising introducing a silicon substrate precursor into a crucible comprising graphite, wherein the crucible does not comprise a plurality of vertical slits; heating the silicon substrate precursor to form molten silicon using an induction heater that surrounds at least a portion of the crucible; and cooling the molten silicon on a cooling wheel that is positioned proximal to the crucible. In some embodiments of the method, heating the silicon substrate precursor does not involve resistance heating. In yet additional embodiments, the induction heater can produce an electromagnetic current sufficient to melt the silicon substrate precursor at a temperature ranging from 1680K to 1690K in a time period ranging from 30 seconds to 10 minutes.

Also disclosed herein are embodiments of silicon substrates made using the systems and methods disclosed herein.

The foregoing and other objects, features, and advantages will become more apparent from the following detailed description, which proceeds with reference to the accompanying figures.

### BRIEF DESCRIPTION OF THE DRAWINGS

FIG. 1 is a photographic image of an exemplary system designed for fabricating ultrathin silicon substrates.

FIG. 2 is an expanded photographic image of an exemplary crucible, induction heater, and copper cooling wheel set-up.

FIG. 3 is another expanded photographic image of the set-up illustrated in FIG. 2.

FIG. 4 is a photographic image of an ultrathin silicon substrate taken out from the chamber of a representative system immediately after deposition of the silicon has occurred.

FIG. 5 is an optical microscopy image of a representative silicon substrate surface.

FIG. 6 is an optical microscopy image of a representative silicon substrate after etching the polished surface in 10% KOH solution at 70° C. for 10 minute, revealing surface grains.

FIG. 7 is a microscopic image of a cross-section of a representative thin silicon substrate.

FIG. 8 is a microscopic image of an edge of a thin silicon substrate showing smooth decrease in thickness.

FIG. 9 is an X-ray diffraction (XRD) spectrum illustrating XRD data of a representative thin silicon substrate, where polycrystalline silicon peaks are observed.

FIG. 10 is an X-ray photoelectron (XPS) spectrum of a thin silicon substrate directly solidified from a melt.

FIG. 11 is an X-ray photoelectron (XPS) spectrum of a thin silicon substrate directly solidified from a melt.

FIG. 12 is an X-ray photoelectron (XPS) spectrum of a thin silicon substrate directly solidified from a melt.

### DETAILED DESCRIPTION

### I. EXPLANATION OF TERMS

The following explanations of terms are provided to better describe the present disclosure and to guide those of ordinary skill in the art in the practice of the present disclosure. As used herein, “comprising” means “including” and the singular forms “a” or “an” or “the” include plural references unless the context clearly dictates otherwise. The term “or” refers to a single element of stated alternative elements or a combination of two or more elements, unless the context clearly indicates otherwise.

The disclosed systems, materials, and methods are not limited to any specific aspect or feature or combinations thereof, nor do the disclosed systems, materials, and methods require that any one or more specific advantages be present or problems be solved. Any theories of operation are to facilitate explanation, but the disclosed systems, materials, and methods are not limited to such theories of operation.

Although the operations of some of the disclosed methods are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed systems, materials, and methods can be used in conjunction with other systems, materials, and methods. Additionally, the description sometimes uses terms like “produce” and “provide” to describe the disclosed methods. These terms are high-level abstractions of the actual operations that are performed. The actual operations that correspond to these terms will vary depending on the particular implementation and are readily discernible by one of ordinary skill in the art.

In some examples, values, procedures, or systems are referred to as “lowest,” “best,” “minimum,” or the like. It will be appreciated that such descriptions are intended to indicate that a selection among many used functional alternatives can be made, and such selections need not be better, smaller, or otherwise preferable to other selections.

Examples are described with reference to directions indicated as “above,” “below,” “upper,” “lower,” and the like. These terms are used for convenient description, but do not imply any particular spatial orientation.

Unless explained otherwise, all technical and scientific terms used herein have the same meaning as commonly understood to one of ordinary skill in the art to which this disclosure belongs. Although methods and materials similar or equivalent to those described herein can be used in the practice or testing of the present disclosure, suitable methods and materials are described below. The materials, methods, and examples are illustrative only and not intended to be limiting, unless otherwise indicated. Other features of the disclosure are apparent from the following detailed description and the claims.

Unless otherwise indicated, all numbers expressing quantities of components, molecular weights, percentages, temperatures, times, and so forth, as used in the specification or claims are to be understood as being modified by the term “about.” Accordingly, unless otherwise indicated, implicitly or explicitly, the numerical parameters set forth are approximations that can depend on the desired properties sought and/or limits of detection under standard test conditions/methods. When directly and explicitly distinguishing embodiments from discussed prior art, the embodiment numbers are not approximates unless the word “about” is recited. Furthermore, not all alternatives recited herein are equivalents.

### II. INTRODUCTION

As the demand for cheaper silicon substrates and reductions of the total cost in device manufacturing increase, attempts have been made in the art to fabricate thin silicon substrates (such as less than 100 μm) by various techniques including edge stabilized growth (ESG), edge-defined film-fed growth (EFG), and ribbon growth on substrate (RGS). These techniques, however, have had limited success owing to the inability to control growth parameters due to the inability to control, for example, pulling speed, temperature, and properties of the supporting substrate. It is currently believed that most, if not all, commercially available thin silicon substrates have thicknesses of at least 100 μm or higher. While silicon substrates having thicknesses less than 100 μm have been reported in the literature, methods for making these silicon substrates require thickness defining materials, such as graphite or boron nitride (BN) and exfoliation techniques. Accordingly, such methods suffer from low growth speed and high production costs due to the extra-space for instrument installation and therefore are not suited for industrial scale operations. Conventional melt-spinning methods for making silicon substrates utilize resistive heating and quartz crucibles. Such methods require long reaction times (typically more than 10 hours, even days) to prepare silicon substrates. Such methods produce silicon substrates that are not pure and require further manipulation to achieve pure silicon substrates suitable for commercial use.

The disclosed methods and systems can be used to cure the deficiencies of conventional techniques. The disclosed methods and systems can be used to make silicon substrates, including thin silicon substrates, at low cost and without the complexity of certain conventional techniques. Additionally, because the disclosed methods and systems can be used to make thin silicon substrates directly, they can be used to quickly produce light weight silicon substrates, to reduce the defect density of the silicon substrates, and to reduce the number of grain-boundaries thereby promoting a longer minority carrier lifetime. The disclosed thin silicon substrates made using the methods disclosed herein can be used in a variety of applications, including three-dimensional integrated circuits (3D ICs) applications, which can contain multiple layers of active devices enhancing performance and device packing density.

The presently disclosed methods and systems can be used to obtain silicon substrates having desired properties that are not sacrificed during production, whereas such properties often are sacrificed using conventional techniques. In some embodiments, the methods utilize heating techniques that are faster than conventional methods, with some embodiments taking a total of only 30 minutes (excluding the time needed to create the desired atmosphere by placing at least certain components of the system under a vacuum) to make the thin silicon substrates. The disclosed methods use a unique combination of inductive heating (with some embodiments not requiring using a crucible comprising a plurality of vertical slits) and system components that can be used to obtain silicon substrates having high purity in a quick and cost-effective manner.

### III. METHODS AND SYSTEMS FOR FORMING SILICON SUBSTRATES

Disclosed herein are embodiments of methods for making silicon substrates. The silicon substrates made using the disclosed methods can be polycrystalline silicon ribbons, wires, rods, or wafers. In some embodiments, the methods can be used to make undoped silicon substrates, n-type silicon substrates, and p-type silicon substrates. Suitable dopants used to make n-type and p-type silicon substrates can be selected from boron, phosphorous, arsenic, gallium, and combinations thereof. In some embodiments, the silicon substrates are thin silicon substrates with thicknesses ranging from as low as 15 μm to 100 μm. Such thin silicon substrates are described in more detail below. Also disclosed herein are embodiments of systems that can be used in the disclosed methods to make the silicon substrates. The methods, silicon substrates, and systems are disclosed in more detail below.

The system embodiments described herein comprise components having unique features and configurations that promote the ability to make silicon substrates having surprisingly unexpected characteristics. For example, in some embodiments the silicon substrates are much thinner than can be achieved using conventional techniques, such as the edge stabilized growth (ESG), edge-defined film-fed growth (EFG), and ribbon growth on substrate (RGS) techniques described above. The disclosed methods use inductive heating to produce silicon substrates in a fraction of the time required for conventional melt-spinning techniques. In some embodiments, the disclosed methods can be used to produce silicon substrates more than 10 times faster than conventional melt-spinning techniques that utilize resistive heating. The systems described herein utilize unique components that contribute to the efficiency of the disclosed methods. The inventors have surprisingly discovered that the unique combination of a crucible as described herein and induction heating can provide silicon substrates with improved purity and at surprisingly fast reaction times.

In some embodiments, the system comprises an induction heater, a crucible, a wheel, and a z-axis crucible holder controller (which, in some embodiments, can be part of the crucible). The induction heater comprises a conductive material capable of translating an electromagnetic current to the crucible resulting in silicon melt formation. In some embodiments, the induction heater comprises copper. In some embodiments, the induction heater can comprise an induction coil comprising copper that surrounds at least a portion of the crucible.

In particular disclosed embodiments, the crucible component comprises graphite. Without being limited to a particular theory, it is currently believed that the graphite crucible can be used to reduce impurities in the silicon substrate due to the drastically shorter period of growth time, whereas other types of crucibles used in conventional methods produce impure silicon substrates. In some embodiments, the crucible can comprise other materials, such as aluminum oxide, graphite, zirconia (or blends thereof), carbides, nitrides, mullite, cordierite, steatite, and combinations thereof. In an independent embodiment, the crucible consists of or consists essentially of graphite. In such embodiments, the crucible does not contain other materials that would affect the purity of the silicon substrate. For example, in such independent embodiments, the crucible is not, or is other than, a quartz crucible. In another independent embodiment, the crucible does not comprise a plurality of vertical slits. In another independent embodiment, the crucible is not, or is other than, the type of crucible comprising a plurality of vertical slits as described in WO2010/044507.

The crucible comprises an opening at the end of the crucible positioned closest to the melt spinner. In some embodiments, the opening can be a circular opening, a rectangular opening, a square opening, or a triangular opening. The shape can be selected according to the type of substrate shape that is to be made. In some embodiments, the length or width of the silicon substrate can be manipulated by modifying the design of the crucible (e.g., its opening shape). In some embodiments, the crucible can comprise three functional sections: a first section used as a holder for z-axis automated controller; a second section used as a tube-rod for checking temperature of melts; and a third section for material loading. The z-axis crucible holder can be a component separate from the crucible, or it can be part of the crucible. The z-axis crucible holder allows the user to vary the vertical position of the crucible from outside of a reaction chamber and therefore does not require breaking the vacuum created in the reaction chamber. Accordingly, vacuum pressures (e.g., 5.5×10⁻⁵ mbar) can be maintained in the chamber.

The wheel can be made of a material suitable for use in melt spinning applications. In some embodiments, the wheel can be made of a metal, such as copper. The wheel can have a diameter ranging from greater than 1 mm to 100 mm or greater, such as 300 mm to 1000 mm, or 50 mm to 300 mm and a width ranging from greater than 1 mm to 100 mm or greater, such as 20 mm to 250 mm, or 20 mm to 70 mm In exemplary embodiments, the wheel was made of copper and had a diameter of 250 mm and a width of 60 mm.

In some embodiments, the system can further comprise a pump, an induction heater controller, a spinner controller, a chamber, and combinations thereof.

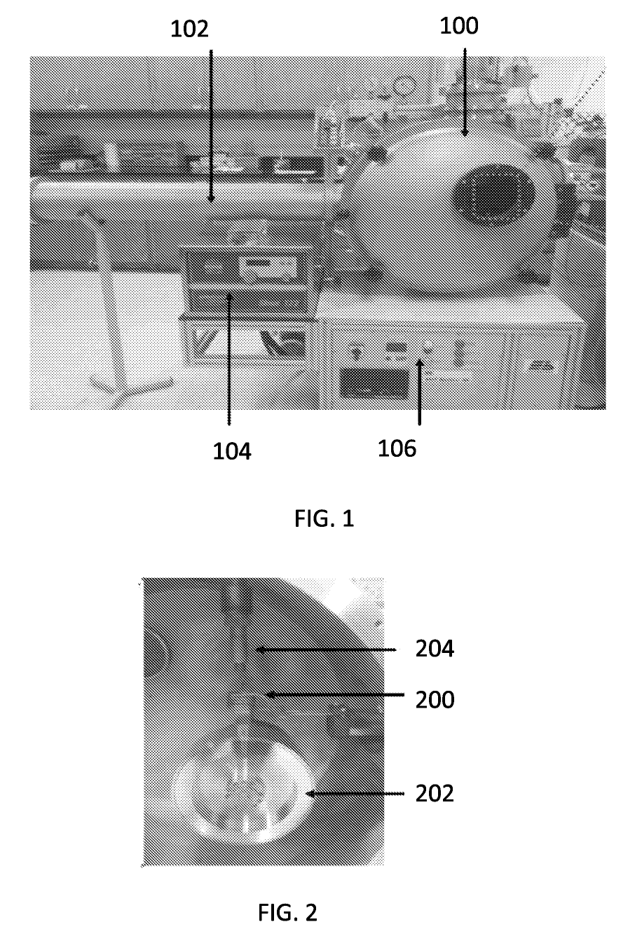

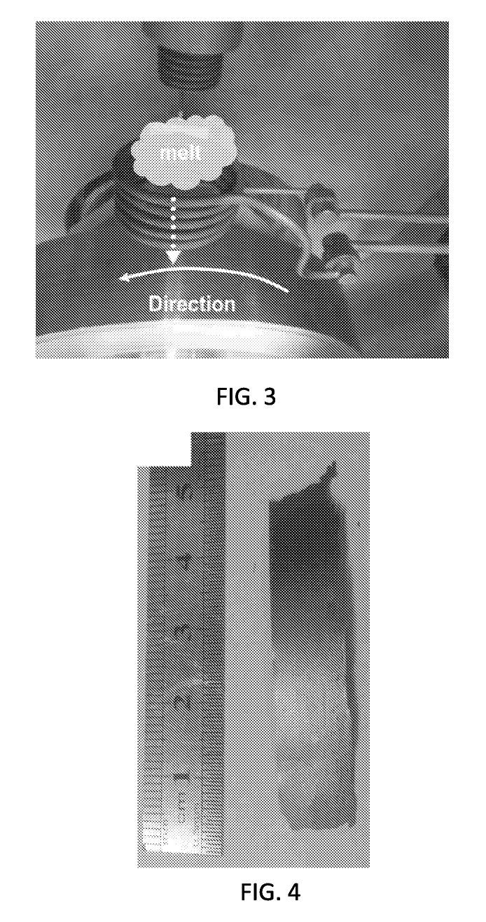

An exemplary system is shown in FIGS. 1-3. The system shown in FIG. 1 comprises a main chamber (100), a substrate collecting tube (102), and controlling mechanisms, such as an induction heater controller (104) and a spinner controller (106). The embodiment illustrated in FIG. 2 includes a copper induction heater (200) connected to an AC generator (not illustrated). A polished copper wheel (202) with 6 cm in width is positioned underneath the copper induction heater (200) in FIG. 2. The vertically placed copper wheel can be positioned at the center of a main reaction chamber. As illustrated in FIGS. 2 and 3, the center of the bottom part of the graphite crucible assembly (204) is located in the middle of the induction heater. The copper wheel shown in FIGS. 2 and 3 rotates at a constant speed depending on the expected substrate thickness while silicon melt is passed through the slit at the bottom of the graphite crucible. In some embodiments, the chamber of the system can be filled with ultra-pure argon gas after raw silicon chips are loaded until the silicon substrate fabrication process ends to prevent oxidation. In some embodiments, once the temperature reaches the melting temperature of silicon (1687K), the molten silicon should remain in a liquid phase. In some embodiments, the temperature can be monitored and maintained by a pyrometric temperature measurement system. The silicon melt can be observed through a quartz glass window from the top of the chamber. The silicon melt is maintained in the liquid phase until the additional pressure is applied onto the melt to release the liquid silicon from the crucible. As soon as liquid silicon passes the slit of the crucible, it contacts the copper wheel resulting in ultrathin silicon substrate formation.

In particular disclosed embodiments, the system is capable of heating the silicon precursor to the temperature at which it melts in fewer than 10 minutes, such as 30 seconds to 6 minutes, or 1 minute to 5 minutes, or 1 minute to 2 minutes, and can provide a homogenous liquid phase of the silicon. This fast heating time can be obtained using the alternating current in combination with the induction heater and the crucible.

The methods of making thin silicon substrates disclosed herein use a unique combination of the components described above, and particularly controlled time and temperature parameters to produce thin silicon substrates quickly and cheaply. In some embodiments, the methods comprise introducing a silicon precursor into a receiving section of the crucible, such as the third section of the crucible described above. In some embodiments, an inert gas atmosphere (e.g., argon) is maintained in the reaction chamber. In some embodiments, the reaction chamber can be placed under vacuum (e.g., 5.5×10⁻⁵ mbar) after the silicon precursor is introduced. In some embodiments, the silicon precursor can be silicon chips, which can have diameters of greater than 0 mm to 5 mm One or more purification cycles can be used to remove residual gas elements. Such purification cycles can comprise filling the chamber with argon up to 1 mbar and then evacuating the chamber under vacuum. In some embodiments, three purification cycles were utilized. Pressure can be applied to the liquid silicon by automated valve manipulation when the crucible is lowered to commence silicon substrate formation. This pressure can force the molten silicon through the slit, which directly introduces the molten silicon on the copper wheel rotating at a constant speed. In some embodiments, a constant speed of 25 m s⁻¹. Once the desired silicon substrate is obtained, the reaction chamber can be cooled and the silicon substrates can be collected.

In some embodiments, the method does not utilize a heated plate (e.g., a heated graphite plate) as a supporting substrate or a metal wire to define the width or the length of the substrate. Accordingly, in some embodiments, the disclosed systems and methods are free of, or do not utilize, a supporting substrate, such as a graphite substrate, or a metal wire.

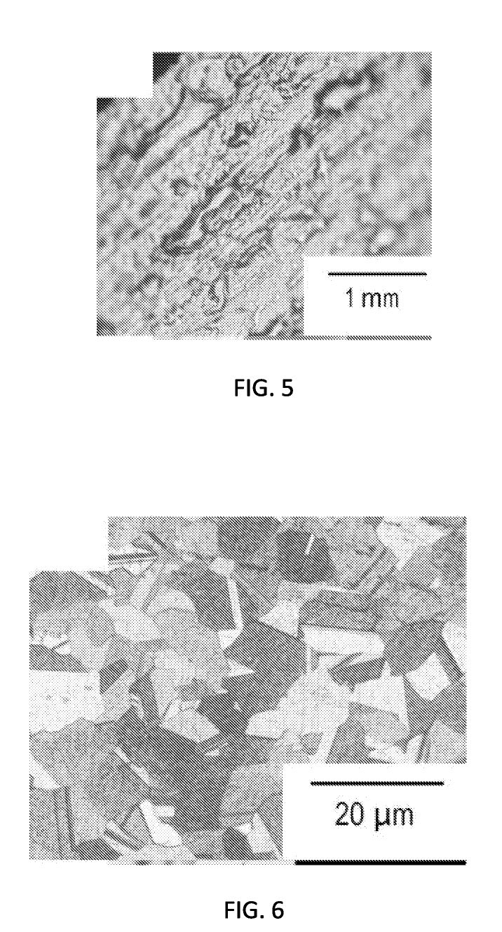

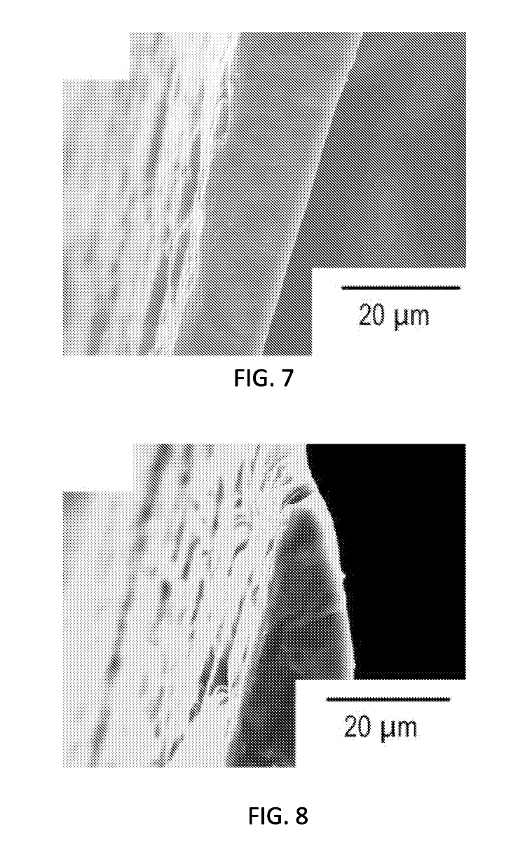

FIGS. 4-8 illustrate exemplary embodiments of silicon substrates made using the methods disclosed herein. FIG. 4 is a photographic image illustrating a thin silicon substrate made using a system and method embodiment as disclosed herein. FIGS. 4-8 are optical microscopy images of grown silicon substrate and field emission scanning electron microscopy images of the planar and cross section of silicon substrate made by a method embodiment disclosed herein. As illustrated in FIG. 4, a grey-colored silicon substrate was formed with a method embodiment using a constant speed of 25 m·s⁻¹ for a copper wheel. With reference to this embodiment, there was no residue on copper wheel after the process ended, thus indicating that all of the silicon melt was consumed along with rotational direction. As illustrated in FIG. 5, the surface of a particular embodiment of a silicon substrate comprised grains in the direction of propagation, but the elongated grains are not found anywhere in the etched microstructure as shown in FIG. 6. In some embodiments, polycrystalline silicon grains (which can be observed by optical microscopy) can be imaged after a grown silicon substrate is polished and etched in 10% KOH solution for a particular time period (e.g., 10 minutes). In some embodiments, twins passing all the way through a grain can be detected. Without being limited to a particular theory of operation, it is currently believed that such a result can indicate a large difference of the growth rate of grains in some embodiments. Unlike ingot growth techniques, which normally produce elongated grains towards growth or pulling direction, the disclosed silicon substrates do not exhibit undesirable grain directions or formations.

In some embodiments, the morphology of the as-grown silicon substrates can be rough (e.g., see FIG. 5). Without being limited to a particular theory of operation, it is currently believed that the roughness of the copper wheel can cause the silicon melt to mimic the surface roughness of copper wheel during the initial stage of the growth. Thus, embodiments using a smooth copper wheel can be used to solve this potential issue. Another potential reason for embodiments exhibiting rough surfaces may relate to the time associated with cooling to promote silicon atom diffusion, coalescence, and rearrangement. In some embodiments, growth can occur within a few seconds thereby causing liquid silicon to be abruptly solidified within a few nanoseconds. In some embodiments, extremely fast cooling rate is evidenced by no elongation of grains. This can be achieved by cooling the wheel through the use of electric based cooling devices, or chilled water based circulation, or chilled air, or nitrogen. In some embodiments, the edge of the silicon substrate can have a smooth decrease in thickness, which can occur due to the dynamic combination of centrifugal force (which, in some embodiments can be 2.5 N for 1 g of silicon), friction, and lateral force together when the molten silicon arrives on the surface of the wheel.

FIG. 9 shows an XRD plot obtained from a representative as-grown silicon substrate without further surface treatment or cleaning. Unlike conventional techniques used in the art, the methods disclosed herein do not use a supplemental substrate, such as a graphite plate or a wire. In some embodiments, the ability to avoid using such components can provide the further advantage of avoiding additional method steps needed to examine the as-grown silicon substrate using XRD, such as delamination steps needed in conventional techniques to install a silicon substrate on an XRD sample holder. In some embodiments, the XRD data obtained from examining the disclosed silicon substrates indicates that only polycrystalline silicon peaks are produced and thus the disclosed methods are suitable for pure silicon substrate fabrication, particularly for silicon substrates having a polycrystalline structure. In some embodiments, the methods used to make the silicon substrates prevent the reaction of oxygen and carbon with silicon and thereby do not produce SiOₓ or SiC species.

In some embodiments, the thin silicon substrates have thicknesses ranging from greater than 0 μm to less than 20 μm, such as greater than 0 μm to 15 μm, such as 5 μm to 15 μm. In some embodiments, the silicon substrates made using the disclosed methods can have widths ranging from 2 mm to 250 mm, such as 2 mm to 70 mm, or 70 mm to 100 mm, or 100 mm to 250 mm and lengths ranging from 10 mm to 10,000 mm, such as 50 mm to 1000 mm, or 10 mm to 50 mm In an exemplary embodiment, a representative silicon substrate was produced directly from molten silicon and had a thinness of 20 μm, and was 1 cm in width and 5 cm in length.

As indicated herein, silicon substrates formed using the methods and systems disclosed herein are produced as very thin substrates of pure silicon. In some embodiments, the substrates can comprise some micro-grains while exhibiting polycrystalline silicon structures. The methods and systems disclosed herein for making polycrystalline, thin silicon substrates can be used to significantly lower production costs for mass production of silicon solar cells.

### IV. EXAMPLES

Material synthesis: Ultrathin silicon substrates were prepared by melt-spinner (Edmund Bühler GmbH) under argon atmosphere to prevent oxidation resulting in SiO₂ formation. 5 g of silicon chips less than 5 mm in diameter were loaded into the graphite crucible followed by pumping down the chamber as low as 5.5×10⁻⁵ mbar. To remove residual gas elements, the chamber was washed out by filling the chamber with argon up to 1 mbar for 3 times. Rapidly solidified silicon substrates were obtained by direct introduction of molten silicon on the copper wheel rotating on the constant speed of 25 m s⁻¹. Without further purification or heat treatment, the chamber was left for 20 minutes for cooling and silicon substrates were collected.

Material characterization: XRD measurements were performed by PANanlytical X-pert pert pro diffractometer at a scanning rate of 0.0125 degree of step size, holding 30 seconds per step from 10 to 90 degrees with Cu Kα radiation. The sample was mounted on a zero background plate using double sided tape to make the sample as flat as possible. The thickness of silicon substrate was measured using a Hitachi S-4700 field emission scanning electron microscope operated at 20 kV. X-ray photoelectron spectroscopy, X-ray source of monochromated Al Kα with 0.7 eV linewidth, was used for investigating the elemental composition and the associated chemical bonding states of the surface region of a silicon substrate. A silicon substrate was exposed to air for 5 days and loaded readily in the ultra-high vacuum chamber for XPS analysis.

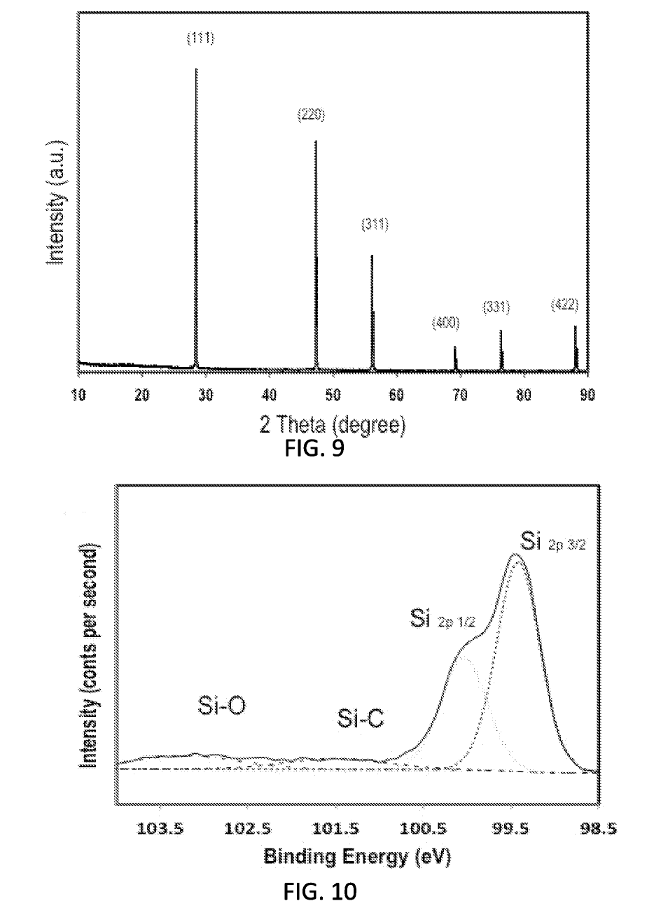

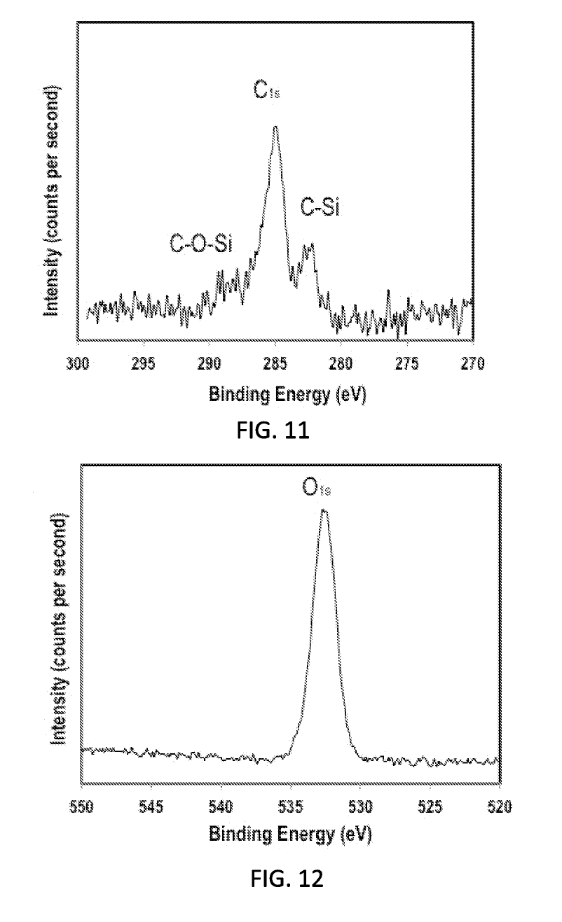

FIGS. 10-12 are XPS spectra consisting of peaks for Si₂ₚ at 99.5 eV, O₁ₛ peak at 532.7 eV, and a C₁ₛ peak at 285 eV [(a) Si₂ₚ peak consisting two spin states of silicon core level with C—Si, and O—Si bonding status, (b) C₁ₛ peak containing C—Si bonding and C—O—Si bonding status, and (c) O₁ₛ symmetrical peak]. Two peaks for the Si₂ₚ core level can be taken into account the Si_{2p 3/2} and Si_{2p 1/2} spin states. Si₂ₚ spectra are also composed of additional chemical bonding status with oxygen and carbon where low binding energy is associated with C—Si and the higher binding energy is associated with O—Si bonding. The intensity of Si—O line is notable but not a significantly observed because the surface of silicon substrate is not fully oxidized that is in accordance with XRD data. In addition, a silicon substrate has been exposed to air for 5 days before the measurement, it is understood that the residual oxygen are responsible for oxygen-related peak illustrated in FIGS. 11 and 12.

Interestingly, a carbon peak at 282.2 eV indicating C—Si bonding status is clearly distinguishable. Moreover, a very weak SiₓC_{y}O_{z} peak is observed at higher binding energy which is attributed to, taking into account the measurement condition, SiC has been partially or rarely formed on the surface then it has been covered with oxygen leading a weak signal around 288 eV. As considering the growth condition, a narrow slit at the bottom of graphite crucible for molten silicon extrusion is responsible for this SiC formation only at the surface. However, SiC was not detected by XRD, which indicates that a minimal amount of SiC has been formed when liquid silicon passes through the slit of 0.3 mm in width.

In view of the many possible embodiments to which the principles of the present disclosure may be applied, it should be recognized that the illustrated embodiments are only preferred examples of the present disclosure and should not be taken as limiting the scope of the disclosure. Rather, the scope of the present disclosure is defined by the following claims.

1. A system for making silicon substrates, comprising:
an induction heater;
a crucible comprising graphite and having a vertical axis, wherein the crucible does not comprise a plurality of vertical slits;
a cooling wheel having a circumferential surface configured to rotate along an axis perpendicular to the vertical axis of the crucible; and
a reaction chamber.

2. The system of claim 1, wherein the induction heater is positioned so as to surround at least a portion of the crucible.

3. The system of claim 1, wherein the induction heater produces an electromagnetic current sufficient to melt a silicon substrate precursor.

4. The system of claim 3, wherein the induction heater heats the silicon substrate precursor to a temperature ranging from 1680K to 1690K in a time period ranging from 30 seconds to 10 minutes.

5. A system for making silicon substrates, comprising:
a crucible consisting of graphite and having a vertical axis, wherein the crucible does not comprise a plurality of vertical slits;
an induction heater positioned to surround at least a portion of the crucible;
a copper cooling wheel having a circumferential surface configured to rotate along an axis perpendicular to the vertical axis of the crucible and positioned proximal to the crucible; and
a reaction chamber that surrounds the crucible, the induction heater, and the copper cooling wheel.

6. A method for making silicon substrates, comprising:
introducing a silicon substrate precursor into a crucible comprising graphite and having a vertical axis, wherein the crucible does not comprise a plurality of vertical slits;
heating the silicon substrate precursor to form molten silicon using an induction heater that surrounds at least a portion of the crucible; and
cooling the molten silicon on a cooling wheel having a circumferential surface that is positioned proximal to the crucible by distributing the molten silicon along the vertical axis of the crucible onto the circumferential surface of the cooling wheel as it rotates along an axis perpendicular to the vertical axis of the crucible.

7. The method of claim 6, wherein heating the silicon substrate precursor does not involve resistance heating.

8. The method of claim 7, wherein the induction heater produces an electromagnetic current sufficient to melt the silicon substrate precursor at a temperature ranging from 1680K to 1690K in a time period ranging from 30 seconds to 10 minutes.

9. A silicon substrate made using the method of claim 6.

10. A silicon substrate made using the system of claim 1.
